(19) United States
(12) Patent Application Publication
(10) Pub. No.: US 2021/0057904 A1
(43) Pub. Date: Feb. 25, 2021

(54) APPARATUS FOR PROTECTING DEVICE OF MOTOR DRIVE INVERTER

(71) Applicants: HYUNDAI MOTOR COMPANY, Seoul (KR); KIA MOTORS CORPORATION, Seoul (KR)

(72) Inventors: Ji Woong Jang, Hwaseong (KR); Sang Cheol Shin, Suwon-si (KR); Yoo Jong Lee, Osan-si (KR); Ki Jong Lee, Osan-si (KR); Kang Ho Jeong, Changwon-si (KR)

(21) Appl. No.: 16/929,479

(22) Filed: Jul. 15, 2020

(30) Foreign Application Priority Data
Aug. 20, 2019 (KR) 10-2019-0101576

(51) Int. Cl. H02H 7/122; H02P 29/024

(52) U.S. Cl. CPC H02H 7/122; H02P 29/027

(57) ABSTRACT

An apparatus for protecting a device of a motor drive inverter includes a plurality of power modules configured to control the multi-phase alternating current supplied to the motor. Each of the plurality of power modules includes a top phase switching device connected to a positive terminal of the battery, a bottom phase switching device connected in series to the top phase switching device and connected to a negative terminal of the battery, and a current interruption unit connected in series to the top phase switching device and the bottom phase switching device, and configured to be disconnected when a current greater than or equal to a desired interrupting current flows thereto, so as to prevent a switching device of a power module from being burned out due to an overcurrent by installing a fuse wire to the power module.

### CROSS-REFERENCE TO RELATED APPLICATION

The present application claims the benefit of priority to Korean Patent Application No. 10-2019-0101576 filed on Aug. 20, 2019 in the Korean Intellectual Property Office, the entire disclosure of which is incorporated herein by reference.

### TECHNICAL FIELD

The present disclosure relates to an apparatus for protecting a device of a motor drive inverter. More particularly, it relates to an apparatus for protecting a device of a motor drive inverter, which serves to protect a device of a power module that controls a drive current supplied to a motor.

### BACKGROUND

In general, eco-friendly vehicles such as battery electric vehicles (BEVs), hybrid electric vehicles (HEVs), plug-in hybrid electric vehicles (PHEVs), and fuel cell electric vehicles (FCEVs) use an electric motor as a drive source, and are equipped with an inverter for controlling the current supplied to the electric motor to drive it.

The inverter is provided with a power module that controls the current for driving the motor, and the power module includes switching devices that may control a current. The switching devices may each be a silicon (Si) based transistor, such as an insulated gate bipolar transistor (IGBT), or a silicon carbide (SiC) based power semiconductor.

The switching devices such as the transistor and the power semiconductor have a maximum operating temperature so that the inverter has a cooler mounted thereto to cool the switching devices. In order to efficiently cool the constituent switching devices of the inverter, a modular structure is used to insulate and waterproof the switching devices.

However, each switching device of the inverter may be burned out when a current greater than the operating current (rated current) of the switching device is supplied to the switching device. In addition, when the switching device is burned out, there is a danger that the internal circuit of the inverter is short-circuited to result in a fire.

The above information disclosed in this Background section is only for enhancement of understanding of the background of the present disclosure and therefore it may contain information that does not form the prior art that is already known in this country to a person of ordinary skill in the art.

### SUMMARY OF THE DISCLOSURE

The present disclosure has been made in an effort to solve the above-described problems associated with prior art.

In an aspect, the present disclosure provides an apparatus for protecting a device of a motor drive inverter, which serves to prevent a switching device of a power module from being burned out due to an overcurrent.

In a preferred embodiment, an apparatus that converts a direct current supplied from a battery into a multi-phase alternating current to be supplied to a motor. The apparatus includes a plurality of power modules configured to control the multi-phase alternating current supplied to the motor. Each of the power modules includes a top phase switching device connected to a positive terminal of the battery, a bottom phase switching device connected in series to the top phase switching device and connected to a negative terminal of the battery, and a current interruption unit connected in series to the top phase switching device and to the bottom phase switching device, and configured to be disconnected when a current greater than or equal to a desired interrupting current flows thereto.

The current interruption unit may include a top phase fuse wire connected between an emitter terminal of the top phase switching device and a collector terminal of the bottom phase switching device. The current interruption unit may include a bottom phase fuse wire connected between an emitter terminal of the bottom phase switching device and the negative terminal of the battery. The top phase fuse wire may have a first end connected to the emitter terminal of the top phase switching device and a second end connected to an output terminal of a respective one of the plurality of power modules, and the collector terminal of the bottom phase switching device may be connected with solder to the output terminal of the power module. The bottom phase fuse wire may have a first end connected to the emitter terminal of the bottom phase switching device and a second end connected to the negative terminal of the battery.

The current interruption unit may have a resistance value that minimizes a power loss caused by the current interruption unit when a maximum operating current is supplied to the top phase and bottom phase switching devices.

Other aspects and preferred embodiments of the present disclosure are discussed infra.

It is understood that the term “vehicle” or “vehicular” or other similar terms as used herein are inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

### BRIEF DESCRIPTION OF THE DRAWINGS

The above and other features of the present disclosure will now be described in detail with reference to certain exemplary embodiments thereof illustrated in the accompanying drawings which are given hereinbelow by way of illustration only, and thus are not limitative of the present disclosure, and wherein:

FIG. 1 is a circuit diagram illustrating an inverter according to one exemplary embodiment of the present disclosure;

FIG. 2 is an illustrative view showing a current interruption unit of a first power module mounted on a substrate according to one exemplary embodiment of the present disclosure;

FIG. 3 is an illustrative view showing a current interruption unit of a second power module mounted on the substrate according to one exemplary embodiment of the present disclosure; and

FIG. 4 is an illustrative view showing a current interruption unit of a third power module mounted on the substrate according to one exemplary embodiment of the present disclosure.

It should be understood that the appended drawings are not necessarily to scale, presenting a somewhat simplified representation of various preferred features illustrative of the basic principles of the present disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

Hereinafter reference will now be made in detail to various embodiments of the present disclosure, examples of which are illustrated in the accompanying drawings and described below. While the present disclosure will be described in conjunction with exemplary embodiments, it will be understood that present description is not intended to limit the disclosure to those exemplary embodiments. On the contrary, the present disclosure is intended to cover not only the exemplary embodiments, but also various alternatives, modifications, equivalents and other embodiments, which may be included within the spirit and scope of the present disclosure as defined by the appended claims.

A motor drive inverter for a vehicle is a power converter capable of converting the direct current output from a battery into a multi-phase alternating current to apply it to a motor. The inverter is configured to control the current supplied to the motor to drive it. The inverter may control the direct current supplied from the battery to apply a multi-phase alternating current to the motor. The inverter generates an alternating current by controlling the direct current depending on the on/off of a switching device. The switching device may be a silicon (Si) based transistor device, such as an insulated gate bipolar transistor (IGBT), a silicon carbide (SiC) based power semiconductor device, or the like.

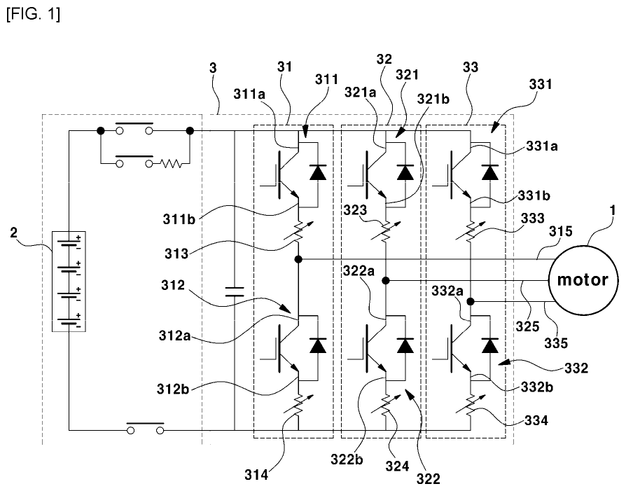

FIG. 1 illustrates a power system for supplying driving power to a motor (i.e., a drive motor) that generates a driving force in a vehicle according to one exemplary embodiment of the present disclosure.

As illustrated in FIG. 1, the power system of the vehicle may include a battery 2 that supplies electric power for driving a motor 1 and an inverter 3 that converts the direct current supplied from the battery 2 into a three-phase alternating current to apply it to the motor 1.

The inverter 3 may include a plurality of power modules 31, 32, and 33 for controlling the phase current supplied to the motor 1 and a capacitor 34 connected in parallel to the power modules 31, 32, and 33. The inverter 3 may include three-phase power modules to generate a three-phase alternating current to be supplied to the motor 1. The three-phase power modules comprise a first power module 31, a second power module 32, and a third power module 33, which are connected in parallel.

The first power module 31 is configured to generate a first phase current from the current supplied from the battery 2 and to control the first phase current. The first power module 31 may include a top phase switching device (hereinafter, referred to as a “1-1 switching device”) 311 and a bottom phase switching device (hereinafter, referred to as a “1-2 switching device”) 312, which are connected in series. A collector terminal 311a of the 1-1 switching device 311 may be connected to a positive terminal 22 of the battery 2, and an emitter terminal 312b of the 1-2 switching device 312 may be connected to a negative terminal 21 of the battery 2.

The second power module 32 is configured to generate a second phase current from the current supplied from the battery 2 and to control the second phase current. The second power module 32 may include a top phase switching device (hereinafter, referred to as a “2-1 switching device”) 321 and a bottom phase switching device (hereinafter, referred to as a “2-2 switching device”) 322, which are connected in series. A collector terminal 321a of the 2-1 switching device 321 may be connected to the positive terminal 22 of the battery 2, and an emitter terminal 322b of the 2-2 switching device 322 may be connected to the negative terminal 21 of the battery 2.

The third power module 33 is configured to generate a third phase current from the current supplied from the battery 2 and to control the third phase current. The third power module 33 may include a top phase switching device (hereinafter, referred to as a “3-1 switching device”) 331 and a bottom phase switching device (hereinafter, referred to as a “3-2 switching device”) 332, which are connected in series. A collector terminal 331a of the 3-1 switching device 331 may be connected to the positive terminal 22 of the battery 2, and an emitter terminal 332b of the 3-2 switching device 332 may be connected to the negative terminal 21 of the battery 2.

The first power module 31 may include a 1-1 fuse wire (or referred to as a “first top phase fuse wire”) 313 disposed between the 1-1 switching device 311 and the 1-2 switching device 312. The 1-1 fuse wire 313 is a current interruption unit of the first power module 31, which is disconnected when a current greater than or equal to a desired interrupting current (specifically, referred to as a “first desired interrupting current”) flows in the first power module 31. The 1-1 fuse wire 313 may be connected in series to the 1-1 switching device 311 and the 1-2 switching device 312. The 1-1 fuse wire 313 may be disposed between an emitter terminal 311b of the 1-1 switching device 311 and a collector terminal 312a of the 1-2 switching device 312.

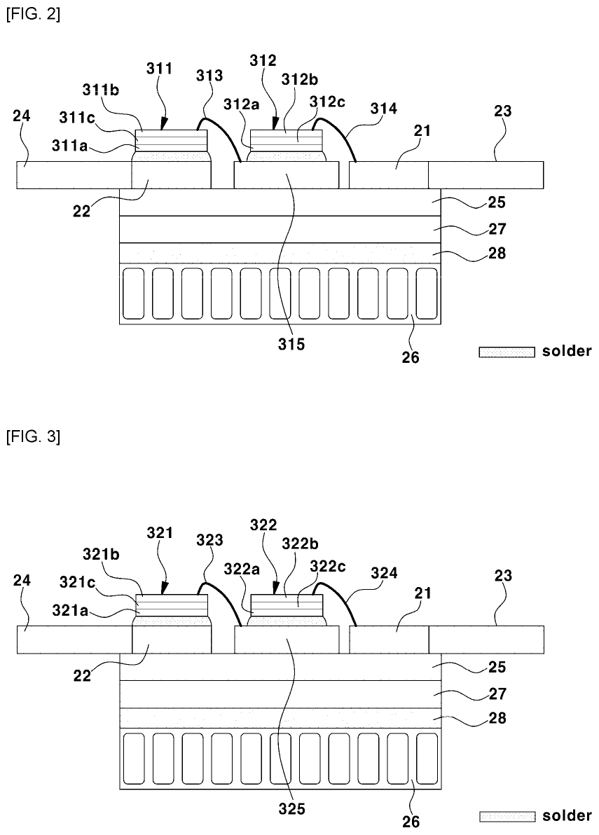

FIG. 2 is an illustrative view showing a current interruption unit of a first power module mounted on a substrate according to one exemplary embodiment of the present disclosure.

As illustrated in FIG. 2, one end (i.e., a first end) of the 1-1 fuse wire 313 may be directly bonded and connected to the emitter terminal 311b of the 1-1 switching device 311, and the other end (i.e., a second end) of the 1-1 fuse wire 313 may be directly bonded and connected to an output terminal (hereinafter, referred to as a “first output terminal”) 315 of the first power module. Referring to FIG. 1, the first output terminal 315 is a circuit for applying the phase current of the first power module 31 to the motor 1 and may be connected between the emitter terminal 311b of the 1-1 switching device 311 and the collector terminal 312a of the 1-2 switching device 312. Specifically, the first output terminal 315 may be connected between the emitter terminal 311b of the 1-1 switching device 311 and the first end of the 1-1 fuse wire 313.

In addition, the first power module 31 may include a 1-2 fuse wire (or referred to as a “first bottom phase fuse wire”) 314 disposed between the emitter terminal 312b of the 1-2 switching device 312 and the negative terminal 21 of the battery 2. The 1-2 fuse wire 314 is another current interruption unit of the first power module 31, which is disconnected when a current greater than or equal to the set first desired interrupting current flows in the first power module 31.

As further illustrated in FIG. 2, one end (i.e., a first end) of the 1-2 fuse wire 314 may be directly bonded and connected to the emitter terminal 312b of the 1-2 switching device 312, and the other end (i.e., a second end) of the 1-2 fuse wire 314 may be directly bonded and connected to the negative terminal 21 of the battery 2.

The negative terminal 21 and positive terminal 22 of the battery 2 and the first output terminal 315 may be circuits printed on a substrate 25, and may be made of a metal material such as copper. The negative terminal 21 of the battery 2 may be connected to the first output terminal 315 through a negative bus bar 23, and the positive terminal 22 of the battery 2 may be connected to the collector terminal 311a of the 1-1 switching device 311 through a positive bus bar 24. The collector terminal 311a of the 1-1 switching device 311 may be soldered on and fixed to the positive terminal 22 of the battery 2, and the collector terminal 312a of the 1-2 switching device 312 may be soldered on and connected to the first output terminal 315. Such a circuit structure may be applied to the second power module 32 and the third power module 33 in the same manner.

The second power module 32 may include a 2-1 fuse wire (or referred to as a “second top phase fuse wire”) 323 disposed between the 2-1 switching device 321 and the 2-2 switching device 322. The 2-1 fuse wire 323 is a current interruption unit of the second power module 32. The 2-1 fuse wire 323 is disconnected when a current which is greater than or equal to a desired interrupting current (specifically, referred to as a “second desired interrupting current”) flows in the second power module 32. The 2-1 fuse wire 323 may be disposed between an emitter terminal 321b of the 2-1 switching device 321 and a collector terminal 322a of the 2-2 switching device 322.

FIG. 3 is an illustrative view showing a current interruption unit of a second power module mounted on the substrate according to one exemplary embodiment of the present disclosure.

As illustrated in FIG. 3, one end (i.e., a first end) of the 2-1 fuse wire 323 may be directly bonded and connected to the emitter terminal 321b of the 2-1 switching device 321, and the other end (i.e., a second end) of the 2-1 fuse wire 323 may be directly bonded and connected to an output terminal (hereinafter, referred to as a “second output terminal”) 325 of the second power module. Referring to FIG. 1, the second output terminal 325 is a terminal for applying the phase current generated by the second power module 32 to the motor 1 and may be connected between the emitter terminal 321b of the 2-1 switching device 321 and the collector terminal 322a of the 2-2 switching device 322. Specifically, the second output terminal 325 may be connected between the emitter terminal 321b of the 2-1 switching device 321 and the first end of the 2-1 fuse wire 323. In addition, the second power module 32 may include a 2-2 fuse wire (or referred to as a “second bottom phase fuse wire”) 324 disposed between the emitter terminal 322b of the 2-2 switching device 322 and the negative terminal 21 of the battery 2. The 2-2 fuse wire 324 is another current interruption unit of the second power module 32. The 2-2 fuse wire 324 is disconnected when a current which is greater than or equal to the set second desired interrupting current flows in the second power module 32.

As further illustrated in FIG. 3, one end (i.e., a first end) of the 2-2 fuse wire 324 may be directly bonded and connected to the emitter terminal 322b of the 2-2 switching device 321, and the other end (i.e., a second end) of the 2-2 fuse wire 324 may be directly bonded and connected to the negative terminal 21 of the battery 2.

The third power module 33 may include a 3-1 fuse wire (or referred to as a “third top phase fuse wire”) 333 disposed between the 3-1 switching device 331 and the 3-2 switching device 332. The 3-1 fuse wire 333 is a current interruption unit of the third power module 33. The 3-1 fuse wire 333 is disconnected when a current which is greater than or equal to a desired interrupting current (specifically, referred to as a “third desired interrupting current”) flows in the third power module 33. The 3-1 fuse wire 333 may be connected in series to the 3-1 switching device 331 and the 3-2 switching device 332. The 3-1 fuse wire 333 may be disposed between an emitter terminal 331b of the 3-1 switching device 331 and a collector terminal 332a of the 3-2 switching device 332.

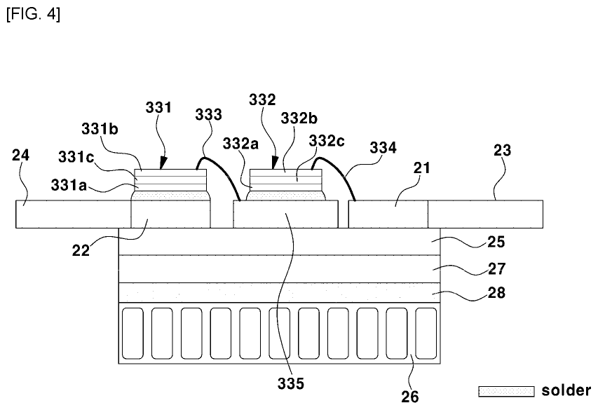

FIG. 4 is an illustrative view showing a current interruption unit of a third power module mounted on the substrate according to one exemplary embodiment of the present disclosure.

As illustrated in FIG. 4, one end (i.e., a first end) of the 3-1 fuse wire 333 may be directly bonded and connected to the emitter terminal 331b of the 3-1 switching device 331, and the other end (i.e., a second end) of the 3-1 fuse wire 333 may be directly bonded and connected to an output terminal (hereinafter, referred to as a “third output terminal”) 335 of the third power module. Referring to FIG. 1, the third output terminal 335 is a circuit for applying the phase current of the third power module 33 to the motor 1 and may be connected between the emitter terminal 331b of the 3-1 switching device 331 and the collector terminal 332a of the 3-2 switching device 332. Specifically, the third output terminal 335 may be connected between the emitter terminal 331b of the 3-1 switching device 331 and the first end of the 3-1 fuse wire 333.

In addition, the third power module 33 may include a 3-2 fuse wire (or referred to as a “third bottom phase fuse wire”) 334 disposed between the emitter terminal 332b of the 3-2 switching device 332 and the negative terminal 21 of the battery 2. The 3-2 fuse wire 334 is another current interruption unit of the third power module 33. The 3-2 fuse wire 334 is disconnected when a current which is greater than or equal to the set third desired interrupting current flows in the third power module 33.

As further illustrated in FIG. 4, one end (i.e., a first end) of the 3-2 fuse wire 334 may be directly bonded and connected to the emitter terminal 332b of the 3-2 switching device 331, and the other end (i.e., a second end) of the 3-2 fuse wire 334 may be directly bonded and connected to the negative terminal 21 of the battery 2. The desired interrupting currents of the first to third power modules 31 to 33 may be set to different current values. That is, when the rated currents of the first switching devices 311 and 312, the rated currents of the second switching devices 321 and 322, and the rated currents of the third switching devices 331 and 332 are different from each other, the desired interrupting currents of the first fuse wires 313 and 314, the desired interrupting currents of the second fuse wires 323 and 324, and the desired interrupting currents of the third fuse wires 333 and 334 may be set differently from each other.

Here, the rated current is a current value set for the normal operation of each switching device. That is, the rated current is an operating current in the range in which the switching device is normally operable. The desired interrupting current is set to a current value that may cause the burnout of each switching device. Each of the fuse wires 313, 314, 323, 324, 333, and 334 is disconnected when a current higher than the desired interrupting current is supplied to the associated switching device 311, 312, 321, 322, 331, or 332 to prevent the burnout of the switching device 311, 312, 321, 322, 331, or 332. For example, the desired interrupting current of the first power module 31 may be set to a current value smaller than the desired interrupting current of the second power module 32.

Further, each of the fuse wires 313, 314, 323, 324, 333, and 334 disposed in the first to third power modules 31 to 33 may have a cross-sectional area and a length that are selected to satisfy conditions such as a predetermined desired impedance, heat-resistant temperature, and interrupting current. That is, the cross-sectional area and length of each fuse wire 313, 314, 323, 324, 333, or 334 may be selected based on the conditions of the desired impedance, heat-resistant temperature, and interrupting current. The reason why the cross-sectional areas and lengths of the fuse wires 313, 314, 323, 324, 333, and 334 are set based on the above conditions is to prevent the fuse wires 313, 314, 323, 324, 333, and 334 from impairing the normal operation of the power modules 31, 32, and 33 and the inverter 3. Accordingly, when the cross-sectional areas and lengths of the fuse wires 313, 314, 323, 324, 333, and 334 are selected without considering the above conditions when wire-bonding is performed to fuse the power modules 31, 32, and 33, the normal operation of the inverter 3 and the driving efficiency of the motor may be impaired.

Specifically, when the maximum operating currents of the 1-1 switching device 311 and the 1-2 switching device 312 flow in the first power module 31, each of the fuse wires 313 and 314 disposed in the first power module 31 may have a resistance value (i.e., a desired impedance) set to 1/10 or less of the on-resistance of the associated switching device 311 or 312. This is to prevent the power efficiency of the inverter 3 from being lowered by minimizing the power loss caused by the fuse wires 313 and 314. In other words, the resistance values of the fuse wires 313 and 314 may be set to values that minimize the power loss caused by the fuse wires 313 and 314 when no overcurrent is supplied to the switching devices 311 and 312. That is, the resistance values of the fuse wires 313 and 314 may be set to values that minimize the power loss caused by the fuse wires 313 and 314 when the maximum operating currents of the switching devices 311 and 312 are supplied to the switching devices 311 and 312. Here, the maximum operating current of each switching device refers to a maximum current value that allows a current to flow to the switching device without burnout thereof. The maximum operating current may be set to a maximum rated current value of the switching element.

The first fuse wires 313 and 314 may be configured such that the first fuse wires 313 and 314 are not disconnected by repetitive thermal expansion occurring during the normal operation of the inverter 3. That is, the first fuse wires 313 and 314 are configured so as not to be disconnected by repetitive thermal expansion that may occur when a current less than the desired interrupting current flows in the first power module 31. To this end, the desired heat-resistant temperature (i.e., the maximum heat-resistant temperature) of each of the first fuse wires 313 and 314 may be set to a certain value. As the desired heat-resistant temperature of the first fuse wire 313 or 314 is set to the certain value, the first fuse wire 313 or 314 may be prevented from being disconnected during the normal operation of the first power module 31.

In addition, the desired interrupting current of each of the fuse wires 313 and 314 disposed in the first power module 31 may be set to a current value of 10 to 20 times the operating current of the associated first switching device 311 or 312. The desired interrupting current may be set to a current value that causes the burnout of the switching device and the disconnection of the fuse wire. The fuse wire of the power module may be disconnected when the desired interrupting current flows into the fuse wire, so as to prevent the desired interrupting current from continuously flowing to the power module.

The second and third power modules 32 and 33 may be configured such that the desired impedance, heat-resistant temperature, and interrupting current of each of the second and third fuse wires 323, 324, 333, and 334 are set on the same principle as the first power module 31.

As illustrated in FIGS. 2 to 4, a heat transfer unit may be disposed on the lower side of the substrate 25 on which the first to third power modules 31 to 33 are mounted, for assisting heat transfer between the substrate 25 and the cooler 26. The heat transfer unit may include a copper layer 27 disposed on the lower side of the substrate 25 and a thermal grease layer 28 disposed on the lower side of the copper layer 27. The cooler 26 may be disposed on the lower side of the thermal grease layer 28, for cooling the power modules 31, 32, and 33. The copper layer 27 and the thermal grease layer 28 fill a micro-cavity between the substrate 25 and the cooler 26 so that the substrate 25 and the cooler 26 are tightly pressed against each other, thereby allowing heat to be efficiently transferred between the substrate 25 and the cooler 26.

In FIGS. 2 to 4, reference numerals 311c, 312c, 321c, 322c, 331c, and 332c designate base terminals of the respective switching devices 311, 312, 321, 322, 331, and 332.

In accordance with the apparatus for protecting a device of a motor drive inverter of the present disclosure, when an overcurrent greater than the operating current of the switching device is supplied to the switching device, the fuse wire is disconnected so as to prevent the overcurrent from continuously flowing to the switching device. As a result, it is possible to prevent the switching device from being burned out due to the overcurrent.

That is, according to the apparatus, it is possible to prevent the switching device from being burned out due to the overcurrent supplied thereto, and to prevent the occurrence of a short-circuit current due to the burnout of the switching device and the occurrence of a fire due to the short-circuit current.

In particular, the apparatus can prevent problems relating to the burnout of the switching device and caused thereby since the fuse wire interrupts an overcurrent when it is difficult to protect the power module from the overcurrent due to the malfunction of the control unit for the control of the power module.

The present disclosure has been described in detail with reference to preferred embodiments thereof. However, it will be appreciated by those skilled in the art that changes may be made in these embodiments without departing from the principles and spirit of the present disclosure, the scope of which is defined in the appended claims and their equivalents.

What is claimed is:

1. An apparatus that converts a direct current supplied from a battery into a multi-phase alternating current to be supplied to a motor, the apparatus comprising a plurality of power modules configured to control the multi-phase alternating current supplied to the motor, wherein each of the plurality of power modules comprises:
a top phase switching device connected to a positive terminal of the battery;
a bottom phase switching device connected in series to the top phase switching device and connected to a negative terminal of the battery; and
a current interruption unit connected in series to the top phase switching device and the bottom phase switching device, and configured to be disconnected when a current greater than or equal to a desired interrupting current flows thereto.

2. The apparatus of claim 1, wherein the current interruption unit comprises a top phase fuse wire connected between an emitter terminal of the top phase switching device and a collector terminal of the bottom phase switching device.

3. The apparatus of claim 2, wherein the current interruption unit comprises a bottom phase fuse wire connected between an emitter terminal of the bottom phase switching device and the negative terminal of the battery.

4. The apparatus of claim 3, wherein the top phase fuse wire has a first end connected to the emitter terminal of the top phase switching device and a second end connected to an output terminal of a respective one of the plurality of power modules, and the collector terminal of the bottom phase switching device is connected with solder to the output terminal of the respective power module.

5. The apparatus of claim 3, wherein the bottom phase fuse wire has a first end connected to the emitter terminal of the bottom phase switching device and a second end connected to the negative terminal of the battery.

6. The apparatus of claim 1, wherein the current interruption unit has a resistance value that minimizes a power loss caused by the current interruption unit when a maximum operating current is supplied to the top phase and bottom phase switching devices.
